(19) United States
(12) Patent Application Publication
(10) Pub. No.: US 2026/0229387 A1
(43) Pub. Date: Aug. 6, 2026

(54) Cold-Resistant Shielded Wire Assembly for Multi-Functional Power and Signal Transmission in Harsh Environments

(71) Applicant: Logan Phelps Baker, Shelbyville, KY (US)

(72) Inventor: Logan Phelps Baker, Shelbyville, KY (US)

(21) Appl. No.: 19/044,667

(22) Filed: Feb. 4, 2025

(51) Int. Cl. H01B 7/29; H01B 7/08; H01B 7/36; H05K 9/00

(52) U.S. Cl. CPC H01B 7/29; H01B 7/08; H01B 7/361; H01B 7/365; H05K 9/0084; H05K 9/0098

(57) ABSTRACT

The present invention relates to a cold-resistant, shielded wire assembly designed for multi-functional power and data signal transmission in harsh and demanding environments. The wire assembly features conductors composed of tinned copper strands insulated with polyvinyl chloride (PVC) material capable of withstanding temperatures ranging from −40° C. to +105° C. An aluminum foil shielding layer with a 125% overlap rate minimizes electromagnetic interference (EMI), while a semi-matte PVC outer jacket provides enhanced durability, flexibility, and resistance to environmental factors such as moisture, abrasion, and chemicals. The assembly includes fool-proof connectors to ensure proper alignment during use and supports HDMI compatibility for audiovisual systems. Printed identification markings indicate compliance with UL and AWM standards, as well as temperature and voltage ratings, facilitating installation and maintenance. Suitable for industrial, automotive, aerospace, medical, outdoor, and consumer electronic applications, the invention provides a reliable, versatile, and robust solution for modern power and signal transmission challenges.

### BACKGROUND OF THE INVENTION

### Field of Invention

The present invention pertains to the field of electrical connection systems, specifically to a cold-resistant, shielded wire assembly and power connection system designed for high-load current applications. This invention provides an advanced solution for simultaneous power and data signal transmission, incorporating tool-free operation, HDMI connectivity, reverse-polarity protection, and enhanced stability. It is particularly suited for use in environments requiring reliable, interference-free connections, including industrial automation, communication systems, consumer electronics, and outdoor or harsh environmental conditions. The invention further addresses the challenges of traditional connection methods by offering improved efficiency, durability, and ease of installation.

### BRIEF SUMMARY OF THE INVENTION

The present invention provides a cold-resistant, shielded wire assembly and advanced power connection system designed for high-load current and data signal transmission. The system features tinned copper conductors with aluminum foil shielding to ensure interference-free operation, a robust polyvinyl chloride (PVC) jacket for durability in extreme conditions, and fool-proof connectors with reverse-polarity protection for safe and reliable connections. Additionally, the inclusion of HDMI interfaces facilitates precise and stable signal transmission, while a tool-free automatic locking mechanism simplifies installation and reduces errors. This invention is particularly suited for industrial, automotive, communication, and consumer electronic applications requiring high performance, reliability, and ease of use.

### BRIEF DESCRIPTION OF THE FIGURES

FIG. 1: illustrates the structural and functional configuration of the wire assembly, including the positive and negative power socket terminals, HDMI compatibility, and the incorporation of a 2×2.5 square power cord and 2×16 p cable shielded with aluminum foil for enhanced EMI protection.

FIG. 2: The flow chart illustrates the manufacturing process for the cold-resistant, shielded wire assembly, detailing the sequential steps from material selection to quality assurance and final packaging.

### DETAILED DESCRIPTION

The present invention is a highly advanced cold-resistant, shielded wire assembly and power connection system designed to provide simultaneous power delivery and data signal transmission with superior reliability, safety, and efficiency in demanding applications. The system overcomes the limitations of traditional power and data connection systems, including complex installations, signal interference, and insufficient durability, by integrating innovative design elements, high-performance materials, and advanced functionality tailored for industrial, consumer, and environmental needs.

At the core of the invention are the tinned copper conductors, arranged in stranded configurations such as 7/0.12+0.008 MM and 41/0.25+0.008 MM, which provide exceptional electrical conductivity and resistance to oxidation. These stranded conductors are optimized for flexibility, allowing for repetitive bending and movement without compromising electrical performance. Each conductor is insulated with high-grade polyvinyl chloride (PVC) material capable of enduring extreme temperatures from −40° C. to +105° C. This insulation offers robust electrical isolation, mechanical protection, and flexibility, ensuring long-term durability even in harsh operating conditions.

To minimize electromagnetic interference (EMI) and maintain data signal integrity, the assembly incorporates a high-performance shielding system. A layer of aluminum foil is wrapped around the insulated conductors, achieving a 125% overlap rate, which provides comprehensive coverage against EMI and radio-frequency interference (RFI). This shielding is further stabilized with a cotton paper isolation layer, which prevents electrical shorting and improves mechanical stability by separating the shielding layer from the insulated conductors. Together, these features enhance the assembly's ability to deliver clean, interference-free power and data signals in environments with high electrical noise.

The entire wire assembly is encased in a semi-matte, cold-resistant PVC outer jacket. The jacket has a consistent outer diameter of 11.0±0.25 MM and is specifically formulated to withstand exposure to extreme cold, moisture, chemical agents, and physical abrasion. Its semi-matte finish reduces glare while retaining flexibility and mechanical durability, ensuring compatibility with various industrial and consumer applications. Additionally, the wire assembly includes filling components between conductors to maintain structural integrity and prevent deformation during bending or installation.

The system is equipped with fool-proof connectors to ensure safe, reliable, and error-free assembly. These connectors feature positive and negative terminals with diameters of 2.5 MM and 3.5 MM, respectively, and are mechanically keyed to prevent incorrect orientation or polarity errors. The connectors utilize a tool-free automatic locking mechanism, which significantly simplifies installation, reduces assembly time, and eliminates the need for specialized tools. This innovation enhances usability while maintaining secure and stable connections even under vibration or movement.

The invention further includes HDMI compatibility, enabling precise and stable data signal transmission alongside power delivery. This feature supports seamless integration with audiovisual and communication systems, ensuring minimal signal degradation and interference. The combination of HDMI connectivity and robust EMI shielding provides exceptional performance for high-quality data-intensive applications, such as video displays, communication modules, and control systems.

The power connection system supports high-load currents of up to 20 A, making it ideal for applications requiring substantial power delivery, such as industrial automation, automotive systems, and communication infrastructure. The system incorporates reverse-polarity protection, which prevents damage to connected devices by eliminating risks associated with incorrect terminal connections. Copper terminals ensure long-term electrical and mechanical stability, offering secure and reliable power delivery in critical applications.

This invention is specifically designed for a broad range of applications, including industrial automation, where quick and reliable connections are essential for operational efficiency; communication systems, where interference-free signal transmission is crucial; consumer electronics, where HDMI compatibility ensures high-quality audiovisual performance; automotive and aerospace applications, where durability and reliability are critical under extreme conditions; and outdoor environments, where resistance to weather and mechanical stresses is required.

The advantages of this invention include simplified installation through a tool-free locking mechanism, enhanced signal stability via HDMI compatibility and multiple shielding layers, improved durability with cold-resistant materials, and increased safety through reverse-polarity protection and mechanically keyed connectors. These features address the limitations of traditional systems, such as cumbersome installation procedures, insufficient shielding, and unreliable connections, offering a highly efficient and reliable solution.

The invention's unique features, such as integrated HDMI interfaces, aluminum foil shielding, cold-resistant PVC jackets, and automatic locking connectors, represent significant advancements over existing technologies. By combining these features, the invention delivers a comprehensive solution for power and data transmission challenges, meeting the demands of modern industries and providing long-term performance and reliability in the most challenging environments.

### DETAILED DESCRIPTION OF FIGURES

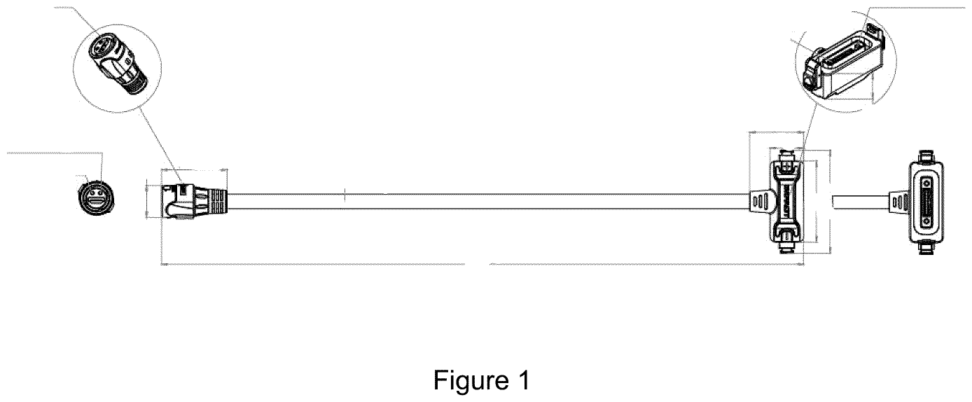

FIG. 1: depicts a comprehensive diagram of the wire assembly, showcasing its key components and their respective functionalities. The assembly includes a negative power socket terminal with a diameter of 3.5 MM and a positive power socket terminal with a diameter of 2.5 MM, both designed to facilitate fool-proof connections and prevent improper alignment during use. The diagram also highlights the assembly's support for HDMI compatibility, emphasizing its capability for combined power and data signal transmission in audiovisual applications. Additionally, the wire assembly incorporates a 2×2.5 square power cord for robust power delivery and a 2×16 p cable for multi-conductor data transmission. To ensure signal integrity and minimize electromagnetic interference (EMI), an additional aluminum foil shielding layer is applied, achieving a high shielding overlap rate. The dimensions and material specifications shown in the figure demonstrate the assembly's suitability for applications requiring durability, reliability, and precise performance across diverse operational contexts.

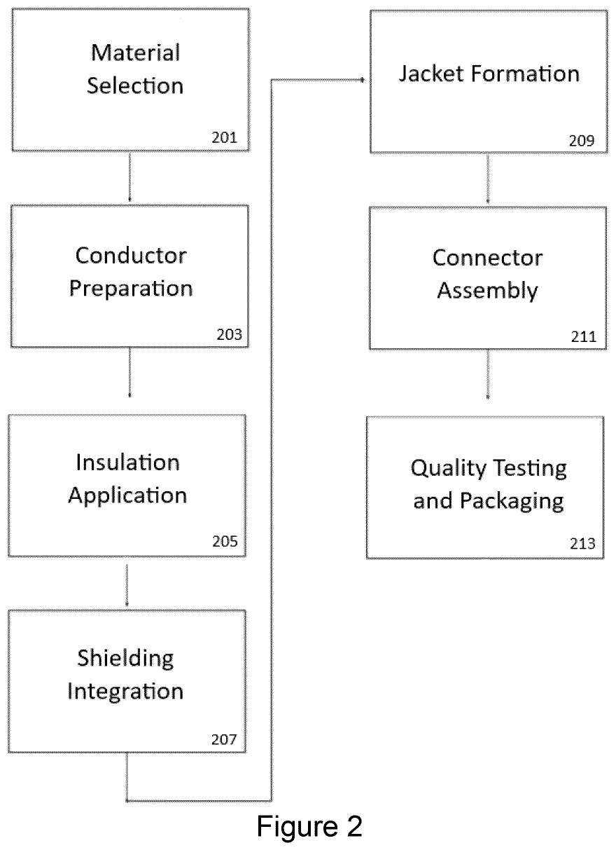

FIG. 2.201: Material Selection—The first step involves selecting the appropriate materials required for constructing the wire assembly. High-quality tinned copper is chosen for its electrical conductivity and resistance to oxidation. Polyvinyl chloride (PVC) with cold-resistant properties is selected for insulation and the outer jacket, while aluminum foil is sourced for shielding, ensuring optimal durability and performance in extreme conditions.

FIG. 2.203: Conductor Preparation—In this step, the tinned copper wires are processed into their required stranded configurations, such as 7/0.12+0.008 MM and 41/0.25+0.008 MM. The strands are twisted using an S-twist configuration to enhance flexibility and mechanical resilience while maintaining uniformity across all conductors.

FIG. 2.205: Insulation Application—Each prepared conductor is encased in a layer of PVC insulation, providing electrical isolation and mechanical protection. The insulation process ensures uniform thickness and adheres to precise diameter specifications to maintain structural integrity and compatibility with subsequent layers.

FIG. 2.207: Shielding Integration—An aluminum foil shielding layer is applied around the insulated conductors, with an overlap rate of 125% to ensure comprehensive EMI protection. Cotton paper isolation is added to separate the shielding layer from the conductors, preventing electrical shorting and enhancing overall stability.

FIG. 2.209: Jacket Formation—The insulated and shielded conductors are encased in a semi-matte PVC outer jacket, which provides additional protection against environmental factors such as moisture, abrasion, and extreme temperatures. The outer jacket is formed to a precise diameter of 11.0±0.25 MM, ensuring consistency for practical installation and use.

FIG. 2.211: Connector Assembly-Fool-proof connectors are attached to the wire assembly, with a positive terminal diameter of 2.5 MM and a negative terminal diameter of 3.5 MM. The connectors are carefully aligned and mechanically secured to prevent improper connections, and HDMI compatibility is ensured during this phase.

FIG. 2.213: Quality Testing and Packaging—The final step involves rigorous quality testing to verify electrical performance, insulation integrity, shielding effectiveness, and connector alignment. The completed assemblies are printed with compliance markings, packaged in full rolls of 100 meters, and prepared for distribution to meet industry standards.

What is claimed is:

1. A cold-resistant shielded wire assembly, comprising:
a. At least one conductor composed of tinned copper strands configured in stranded arrangements of 7/0.12+0.008 MM and 41/0.25+0.008 MM;
b. An insulating layer surrounding each conductor, wherein the insulating layer is composed of polyvinyl chloride (PVC) material capable of withstanding temperatures from −40° C. to +105° C.;
c. A shielding layer comprising aluminum foil with a shielding overlap rate of 125%;
d. A semi-matte, cold-resistant outer jacket composed of PVC material, the outer jacket having an outer diameter of 11.0±0.25 MM; and
e. A printed identification layer on the outer surface of the wire assembly indicating temperature, voltage ratings, and certification compliance.

2. The wire assembly of claim 1, further comprising:
a. A plurality of conductors arranged in a flat cable configuration with a pitch of 1.27 MM for data transmission applications; and
b. A filling material interspersed between conductors to maintain structural integrity during bending or physical manipulation.

3. The wire assembly of claim 1, wherein the aluminum foil shielding layer is separated from the conductors by a cotton paper isolation layer to prevent electrical shorting and to ensure mechanical separation.

4. The wire assembly of claim 1, further comprising fool-proof connectors configured with a positive terminal having a diameter of 2.5 MM and a negative terminal having a diameter of 3.5 MM, wherein the connectors are designed to prevent incorrect connections.

5. The wire assembly of claim 1, wherein the assembly is compatible with HDMI connectors for combined power and data transmission.

6. The wire assembly of claim 1, wherein the outer jacket is resistant to environmental factors including moisture, abrasion, and chemical exposure, enabling operation in harsh outdoor or industrial environments.

7. The wire assembly of claim 1, wherein the conductor insulation includes a color-coded scheme, comprising a red edge and gray base for identification.

8. The wire assembly of claim 3, wherein the aluminum foil shielding achieves electromagnetic interference (EMI) and radio-frequency interference (RFI) reduction to ensure signal integrity during operation.

9. The wire assembly of claim 2, wherein the flat cable configuration is designed for integration into consumer electronics and audiovisual systems requiring multi-functional power and data transmission.

10. The wire assembly of claim 4, wherein the fool-proof connectors are mechanically keyed to ensure proper orientation during mating, reducing connection errors in industrial and automotive systems.

11. The wire assembly of claim 1, wherein the outer jacket includes a semi-matte finish to minimize visual glare while retaining flexibility and durability under repetitive stress.

12. The wire assembly of claim 1, further comprising a printing process for marking compliance with UL and AWM certifications, wherein the printing is performed using a direct printing wheel to ensure long-lasting legibility.

13. The wire assembly of claim 1, wherein the assembly is packaged in full roll packaging, with each roll comprising 100 meters of wire assembly.
